(19) United States
(12) Patent Application Publication
(10) Pub. No.: US 2016/0269046 A1
(43) Pub. Date: Sep. 15, 2016

(54) MEMORY CONTROLLER, MEMORY SYSTEM, AND DECODING METHOD

(71) Applicant: Kabushiki Kaisha Toshiba, Minato-ku (JP)

(72) Inventors: Daiki WATANABE, Yokohama (JP); Osamu TORll, Setagaya (JP); Ryo YAMAKI, Yokohama (JP)

(73) Assignee: Kabushiki Kaisha Toshiba, Minato-ku (JP)

(21) Appl. No.: 14/846,006

(22) Filed: Sep. 4, 2015

Related U.S. Application Data
(60) Provisional application No. 62/131,033, filed on Mar. 10, 2015.

(51) Int. Cl. H03M 13/15; G06F 11/10; H03M 13/00; G06F 3/06

(52) U.S. Cl. CPC H03M 13/151; G06F 3/0619; G06F 3/0661; G06F 3/0679; G06F 11/1008; H03M 13/611

(57) ABSTRACT

A memory controller includes: an encoder configured to generate a block product code which includes a first code and a second code as component codes, the first code and the second code being linear cyclic codes; a memory interface configured to write the block product code to a nonvolatile memory, and to read a received word from the nonvolatile memory; and a decoder configured to perform a decoding using a code constraint corresponding to a generator polynomial as a common divisor between a generator polynomial of the first code and a generator polynomial of the second code with respect to a symbol of an area which is not subjected to a code constraint of the first code but subjected to a code constraint of the second code.

### CROSS-REFERENCE TO RELATED APPLICATIONS

This application is based upon and claims the benefit of priority from U.S. Provisional Application No. 62/131,033, filed on Mar. 10, 2015; the entire contents of which are incorporated herein by reference.

### FIELD

Embodiments described herein relate generally to a memory controller, a memory system, and a decoding method.

### BACKGROUND

In a storage device, generally, data as an error correction code is stored in order to protect the data to be stored. There is a block product code as a type of code having a large code length configured by combining the error correction codes (called a component code) having a small code length.

### BRIEF DESCRIPTION OF THE DRAWINGS

FIG. 1 is a block diagram illustrating an exemplary configuration of a storage device according to an embodiment;

FIG. 2 is a diagram illustrating an exemplary example of a block product code of an embodiment;

FIG. 3 is a diagram illustrating an exemplary example of a decoder of an embodiment;

FIG. 4 is a diagram illustrating an example of a decoding processing procedure of a block product code of an embodiment;

FIG. 5 is a diagram illustrating an exemplary example of a decoder in a case where a turbo decoding is performed;

FIG. 6 is a diagram for describing a soft bit read;

FIG. 7 is a diagram illustrating an example of an LLR table;

FIG. 8 is a diagram illustrating an exemplary configuration of a third decoder of an embodiment;

FIG. 9 is a diagram illustrating that a symbol string {s′_{j′,k}} included in d_{add} is composed by adding symbol strings {s_{i,j,k}} of the original codes;

FIG. 10 is a diagram illustrating an example of a relation between a symbol failed in correction by a code C₂ and a symbol s′_{j*,k*}which is specified as an error in decoding of d_{add}; and

FIG. 11 is a diagram illustrating an example of a decoding procedure on areas of checks2 and checks2 on checks1 of an embodiment.

### DETAILED DESCRIPTION

According to an embodiment, a memory controller includes an encoder which generates a block product code having a first code and a second code (linear cyclic codes) as component codes, and a memory interface which writes the block product code to a nonvolatile memory and reads out a received word corresponding to the block product code from the nonvolatile memory. In addition, the memory controller includes a decoder which performs a decoding using a code constraint corresponding to a generator polynomial as a common divisor between a generator polynomial of the first code and a generator polynomial of the second code with respect to a symbol of an area which is included in the block product code and not subjected to a code constraint of the first code but subjected to a code constraint of the second code.

A memory controller, a memory system, and a decoding method according to an embodiment will be described with reference to the accompanied drawings below. Further, the invention is not limited to the embodiment.

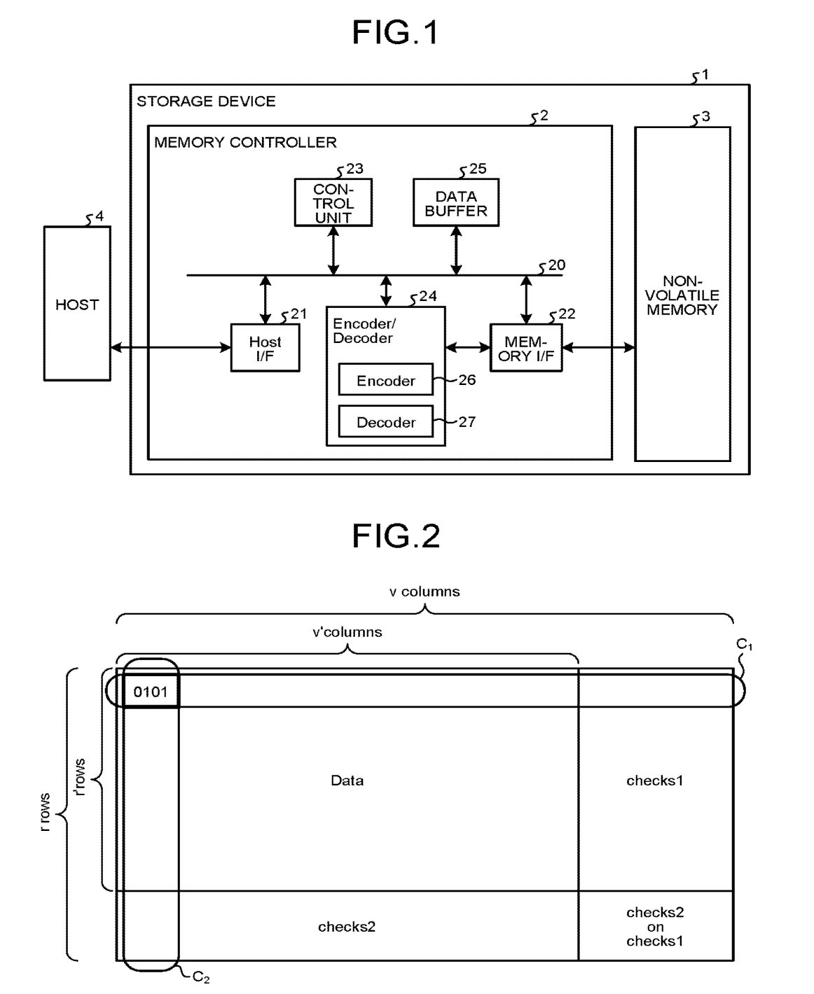

FIG. 1 is a block diagram illustrating an exemplary configuration of a storage device (the memory system) according to an embodiment. A storage device 1 according to this embodiment includes a memory controller 2 and a nonvolatile memory 3. The storage device 1 can be connected to a host 4, and FIG. 1 illustrates a state of the connection with the host 4. The host 4, for example, is an electronic device such as a personal computer or a portable terminal.

The nonvolatile memory 3 is a nonvolatile memory to store data in a nonvolatile manner (for example, a NAND memory). Further, the description herein will be made about an example of a NAND memory used as the nonvolatile memory 3. As the nonvolatile memory 3, any storage member other than the NAND memory such as a three-dimensional flash memory, a resistance random access memory (ReRAM), or a ferroelectric random access memory (FeRAM) may be employed. In addition, the description herein will be made about an example of a semiconductor memory used as the storage member. An error correction process according to this embodiment may be applied to a storage device using a storage member other than the semiconductor memory.

The storage device 1 may be a memory card in which the memory controller 2 and the nonvolatile memory 3 are integrated in one package, or may be a solid state drive (SSD).

The memory controller 2 controls writing onto the nonvolatile memory 3 in response to a write command (request) from the host 4. In addition, the memory controller 2 controls reading out of the nonvolatile memory 3 in response to a read-out command from the host 4. The memory controller 2 includes a host I/F (host interface) 21, a memory I/F (the memory interface) 22, a control unit 23, an encoder/decoder 24, and a data buffer 25. The host I/F 21, the memory I/F 22, the control unit 23, the encoder/decoder 24, and the data buffer 25 are connected to each other through an internal bus 20.

The host I/F 21 performs a process according to an interface standard with respect to the host 4, and outputs a command received from the host 4 and user data to the internal bus 20. In addition, the host I/F 21 transmits the user data read out of the nonvolatile memory 3 and a response from the control unit 23 to the host 4. Further, in this embodiment, data to be written into the nonvolatile memory 3 in response to a write request from the host 4 will be referred to as user data.

The memory I/F 22 performs a write process into the nonvolatile memory 3 based on an instruction of the control unit 23. In addition, the memory I/F 22 performs a read process on the nonvolatile memory 3 based on an instruction of the control unit 23.

The control unit 23 is a control unit which collectively controls the respective components of the storage device 1. In a case where a command is received from the host 4 through the host I/F 21, the control unit 23 performs control according to the command. For example, the control unit 23 instructs the memory I/F 22 to write the user data and the writing of redundant data generated by encoding to the nonvolatile memory 3 according to a command from the host 4. In addition, the control unit 23 instructs the memory I/F 22 to read out the user data from the nonvolatile memory 3 according to the command from the host 4.

In addition, in a case where the write request is received from the host 4, the control unit 23 determines a storage area (memory area) on the nonvolatile memory 3 with respect to the user data accumulated in the data buffer 25. In other words, the control unit 23 determines a write destination of the user data. A correspondence between a logical address of the user data received from the host 4 and a physical address indicating the storage area on the nonvolatile memory 3 with the user data stored therein is stored as an address conversion table.

In addition, in a case where the read request is received from the host 4, the control unit 23 converts the logical address designated by the read request into the physical address using the address conversion table, and instructs the memory I/F 22 to perform the reading out of the physical address.

In the NAND memory, the writing and the reading are generally performed in a unit of data called a page, and erasing is performed in a unit of data called a block. In this embodiment, a plurality of memory cells connected to the same word line are called a memory cell group. In a case where the memory cell is a single level cell (SLC), one memory cell group corresponds to one page. In a case where the memory cell is a multi-level cell (MLC), one memory cell group corresponds to a plurality of pages. In addition, each memory cell is connected to the word line and also to a bit line. Each memory cell can be identified using an address for identifying the word line and an address for identifying the bit line. In this embodiment, the writing of one page of data to the same page of the same memory cell group is expressed as a writing to one page of the nonvolatile memory 3.

The data buffer 25 temporarily stores the user data received by the memory controller 2 from the host 4 until the user data is stored in the nonvolatile memory 3. In addition, the data buffer 25 temporarily stores the user data read out of the nonvolatile memory 3 until the user data is transmitted to the host 4. The data buffer 25, for example, is formed by a general purpose memory such as a static random access memory (SRAM) or a dynamic random access memory (DRAM).

The user data transmitted from the host 4 is transferred to the internal bus 20 and stored in the data buffer 25. The encoder/decoder 24 encodes the data stored in the nonvolatile memory 3 and generates a code word. The encoder/decoder 24 includes an encoder 26 and a decoder 27. The encoding and the decoding according to this embodiment will be described in detail in the description of the write process to the nonvolatile memory 3 and the read process from the nonvolatile memory 3 described below.

First, the write process according to this embodiment will be described. At the time of the writing to the nonvolatile memory 3, the control unit 23 instructs the encoder 26 to perform the encoding of the data, determines a storage location (a storage address) of the code word in the nonvolatile memory 3, and instructs the memory I/F 22 with the storage location. The encoder 26 encodes the data on the data buffer 25 to generate the code word based on the instruction from the control unit 23. The memory I/F 22 controls the storing of the code word to the storage location on the nonvolatile memory 3 instructed from the control unit 23.

The encoder 26 generates the block product code. FIG. 2 is a diagram illustrating an exemplary configuration of the block product code according to this embodiment. The block product code is a type of code of which the code length is long and in which an error correction code having a small code length called a component code is combined. The block product code according to this embodiment is an r×v array of a symbol string (block) having a length of b. In addition, the block product code according to this embodiment is made of an r×v array of a symbol string having a length of b. The symbol s included in the block, for example, is a bit, and the symbol s is not limited to the bit. Any symbol may be used as long as the symbol is its own additive inverse. In other words, if a symbol s satisfies s+s=0, s can be used.

As illustrated in FIG. 2, the block product code according to this embodiment is made of a code word group of a component code in a row direction (that is, a horizontal direction illustrated in FIG. 2) and a component code in a column direction (that is, a vertical direction illustrated in FIG. 2). The code word of the component code in the row direction (hereinafter, referred to as a code word in the row direction) and the code word of the component code in the column direction (hereinafter, referred to as a code word in the column direction) intersect in a unit of block. The numeric value in the block at the left upper corner illustrated in FIG. 2 shows an example in the case of b=4, but the FIG. 2 is a mere example and b may be not 4. In addition, the entire code in the code word of a code C₁ (the first code) which is the component code in the row direction is made of b×v symbols, information is made of b×v′ symbols, and the redundant data (check1) is made of b×(v−v′) symbols. The entire code of the code word of a code C₂ (the second code) which is the component code in the column direction is made of b×r symbols, information is made of b×r′ symbols, and the redundant data (check2) is made of b×(r−r′) symbols.

The encoder 26 according to this embodiment first generates r′ code words of the code C₁ in the row direction. Therefore, r rows are generated in the upper portion of the block product code of FIG. 2. In addition, the encoder 26 receives input data which is made of r′×b symbols configured by a q-th block (q indicates a block number in one code word) of each of the r′ rows in the upper portion, and generates the code word of the code C₂ in the column direction. Therefore, there are generated v′ code words in the column direction from the left side of FIG. 2 which is configured by information and check2 generated using the information, and (v−v′) code words in the column direction from the right side of FIG. 2 which is configured by check1 and check2 on checks1 generated using the check1.

In addition, data other than the user data received from the host 4 (for example, data used for the control of the memory controller 2) may be targeted for the encoding. In addition, as the component code, for example, a Bose-Chaudhuri-Hocquenghem (BCH) code, a Reed-Solomon (RS) code, or the like may be employed.

Herein, it is assumed that a k-th symbol of the block (the symbol string) at a row number i and a column number j in the block product code according to this embodiment is denoted by s_{i,j,k}.

Herein, a code word c configured by n symbol strings is denoted by c=(s₀, S₁, s₂, . . . , sₙ₋₁), and a code polynomial c(x) corresponding to the code word c is denoted by the following Equation (1).

$$c ( x ) = {\sum }_{i - 0}^{n - 1} {s}_{i} {x}^{i} \qquad ( 1 )$$

In this case, in the linear cyclic code, the following Equation (2) is established in a polynomial g(x) called a generator polynomial. In other words, c(x) comes to have a remainder of “0” when being divided by g(x).

c(x)≡0 mod g(x) (2)

In addition, the codes C₁ and C₂ of the block product code both are assumed to be the linear cyclic code, and the generator polynomials of the component codes C₁ and C₂ are denoted by g₁(x) and g₂(x), respectively. In this case, when the code polynomial of the code word of an i-th component code C₁ of the block product code is denoted by c₁ᵢ(x), and the code polynomial of the code word of a j-th code C₂ is denoted by c₂ⱼ(x), the following Equations (3) and (4) are established by the above Equation (2).

$$\begin{matrix}{c}_{1 , i} ( x ) = {\sum }_{j = 0}^{v - 1} {\sum }_{k = 0}^{b - 1} {s}_{i , j , k} {x}^{( k + jb )} ≡ 0 mod {g}_{1} ( x ) i ∈ [ 0 , {r}^{′} - 1 ] \\ {c}_{2 , j} ( x ) = {\sum }_{i = 0}^{r - 1} {\sum }_{k = 0}^{b - 1} {s}_{i , j , k} {x}^{( k + ib )} ≡ 0 mod {g}_{2} ( x ) j ∈ [ 0 , v - 1 ] & ( 3 ) \\ {c}_{2 j} ( x ) = {\sum }_{i = 0}^{r - 1} {\sum }_{k = 0}^{b - 1} {s}_{ijk} {x}^{( k + ib )} ≡ 0 mod {g}_{2} ( x ) i ∈ [ 0 , s - 1 ] & ( 4 )\end{matrix}$$

Further, in this description, the left upper side of the block product code corresponds to a term having the lowest degree of the code polynomial, and the right lower side corresponds to a term having a high degree.

The symbol included in the areas of checks2 and checks2 on checks1 in FIG. 2 follows an code constraint equation (4) by the code C₂, but is free from an code constraint equation (3) by the code C₁. On the contrary, among the symbols of the block product code, codes of the area except checks2 and checks2 on checks1 follow the code constraint equation (4) by the code C₂ and also follow the code constraint equation (3) by the code C₁. Therefore, since the symbol included in the areas of checks2 and checks2 on checks1 can be subjected to the error correction by the code C₂ but not subjected to the error correction by the code C₁, the symbol is relatively vulnerable to an error compared to the symbol included in the other areas in the block product code.

In this embodiment, an error correcting performance on the symbol included in the areas of checks2 and checks2 on checks1 can be improved by performing the decoding using another code constraint as well as the code constraint equation (4) by the code C₂ even on checks2 and checks2 on checks1.

The decoding method according to this embodiment will be described. First, a mathematical property of the block product code which is used in the decoding method of the block product code in this embodiment will be described. Further, in this embodiment, the component codes C₁ and C₂ are used as the linear cyclic codes, and a symbol of the codes always is its own additive inverse.

The above Equations (3) and (4) represent equations of the code constraints by the codes C₁ and C₂ which are established in the block product code. Herein, when a greatest common divisor of the generator polynomials g₁ (x) and g₂(x) of the codes C₁ and C₂ is set to g_{gcd}(x), the following Equations (5) and (6) are established from Equations (3) and (4).

$$\begin{matrix} {c}_{1 , i} ( x ) ≡ 0 mod {g}_{gcd} ( x ) i ∈ [ 0 , {r}^{′} - 1 ] & ( 5 ) \\ {c}_{2 , j} ( x ) ≡ 0 mod {g}_{gcd} ( x ) j ∈ [ 0 , v - 1 ] {c}_{2 , j} ( x ) ≡ 0 mod {g}_{gcd} ( x ) j ∈ [ 0 , v - 1 ] & ( 6 )\end{matrix}$$

Herein, when the term obtained by multiplying x^{ib} by the left side of Equation (5) and the term obtained by multiplying x^{jb} by the left side of Equation (6) are added, the following Equation (7) can be derived from Equations (5) and (6).

$$\begin{matrix}{\sum }_{i = 0}^{{r}^{′} - 1} {c}_{1 , i} ( x ) {x}^{ib} + {\sum }_{j = 0}^{v - 1} {c}_{2 , j} ( x ) {x}^{jb σ} = {\sum }_{i = 0}^{{r}^{′} - 1} {\sum }_{j = 0}^{v - 1} {\sum }_{k = 0}^{b - 1} {s}_{i , j , k} {x}^{( k + ib + jb )} + \\ {\sum }_{j = 0}^{v - 1} {\sum }_{i = 0}^{r - 1} {\sum }_{k = 0}^{b - 1} {s}_{i , j , k} {x}^{( k + ib + jb )} \\ = {\sum }_{i = {r}^{′}}^{r - 1} {\sum }_{j = 0}^{v - 1} {\sum }_{k = 0}^{b - 1} {s}_{i , j , k} {x}^{( k + ib + jb )} ≡ \\ 0 mod {g}_{gcd} ( x )\end{matrix} \qquad ( 7 )$$

In this embodiment, the description will be made about an example in which r−r′ is 1. In this case, the above Equation (7) can be expressed as the following Equation (8).

$${\sum }_{j = 0}^{v - 1} {\sum }_{k = 0}^{b - 1} {s}_{{r}^{′} , j , k} {x}^{( k + jb )} {x}^{{r}^{′} b} ≡ {\sum }_{j = 0}^{v - 1} {\sum }_{k = 0}^{b - 1} {s}_{{r}^{′} , j , k} {x}^{( k + jb )} ≡ 0 mod {g}_{gcd} ( x ) \qquad ( 8 )$$

Herein, a symbol group of checks2 and checks2 on checks1 (that is, the symbol group in the lowest one row of the block product code illustrated in FIG. 2) is set to d_{checks2}. The above Equation (7) shows that d_{checks2} belongs to the code constraint of a linear cyclic code C_{gcd} having a code length of v×b in which g_{gcd}(x) is set as the generator polynomial. Therefore, in a case where an error occurs in d_{checks2}, the error can be corrected by applying a decoding algorithm to the code C_{gcd}. Further, herein, the greatest common divisor g_{gcd}(x) is employed, but it is possible to perform the decoding using the code constraint of the linear cyclic code corresponding to the common divisor even just like the case of using the common divisor instead of the greatest common divisor.

Next, the description has been made about an exemplary decoding method of the block product code according to this embodiment using the mathematical property. In this embodiment, a hard decision decoding may be employed as the decoding method of each component code, or a soft decision decoding may be employed. In addition, in a case where the soft decision decoding is performed, there may be employed a decoding method called a turbo decoding in which an external value is exchanged in each component code. memory I/F 22 reads data (a received word) corresponding to the block product code illustrated in FIG. 2 from the nonvolatile memory 3 according to the instruction and stores the data in the data buffer 25. Further, in a case where one code word of the code C₁ of the block product code is stored in one page of the nonvolatile memory 3, and all the block product codes are stored in a plurality of pages, the received word corresponding to one code word of the code C₁ is read first, and then in a case where the decoding of the received word is failed, the block product code may be read.

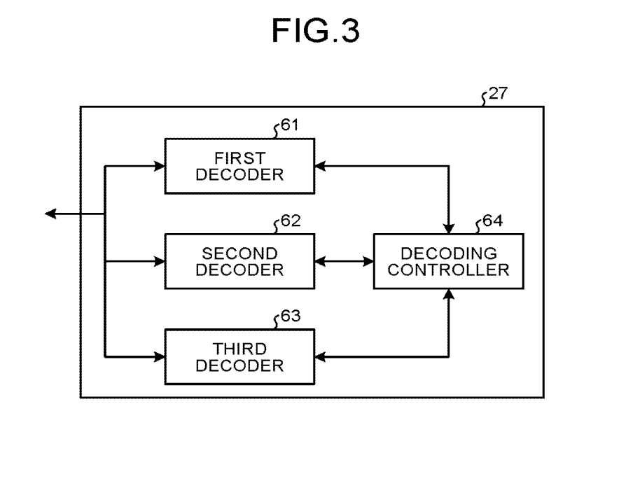

FIG. 3 is a diagram illustrating an exemplary configuration of the decoder 27 according to this embodiment. FIG. 3 illustrates the exemplary configuration of the decoder 27 in a case where the hard decision decoding is performed. As illustrated in FIG. 3, the decoder 27 includes a first decoder 61 which performs the decoding of the code C₁, a second decoder 62 which performs the decoding of the code C₂, a third decoder 63 which performs the decoding of the code C_{gcd}, and a decoding controller 64. Herein, the data read out of the nonvolatile memory 3 stored in the data buffer 25 is assumed to be subjected to the hard decision.

The first decoder 61 performs the decoding (C₁ decoding) corresponding to the code constraint of the code C₁ on the received word which is previously encoded to a C₁ code word stored in the data buffer 25. When an error location is specified through the decoding, the error at the place corresponding to the data buffer 25 is corrected.

The second decoder 62 performs the decoding (C₂ decoding) corresponding to the code constraint of the code C₂ on the received word which is previously encoded to a C₂ code word stored in the data buffer 25. When the error location is specified through the decoding, the error at the place corresponding to the data buffer 25 is corrected.

The third decoder 63 performs the decoding (C_{gcd} decoding) corresponding to the code constraint of the code C_{gcd} on the read data corresponding to the symbol group of checks2 and checks2 on checks1 stored in the data buffer 25 (that is, d_{checks2} in the lowest one row of the block product code illustrated in FIG. 2). When the error location is specified through the decoding, the error at the placed corresponding to the data buffer 25 is corrected.

Any decoding method may be used in the first decoder 61, the second decoder 62, and the third decoder 63, and for example a bounded distance decoding may be employed. In addition, FIG. 3 illustrates an example in which the first decoder 61, the second decoder 62, and the third decoder are individually provided. However, two or more decoding functions of the first decoder 61, the second decoder 62, and the third decoder may be realized by one decoder hardware. Alternatively, some inner circuits of the first decoder 61, the second decoder 62, and the third decoder may be shared.

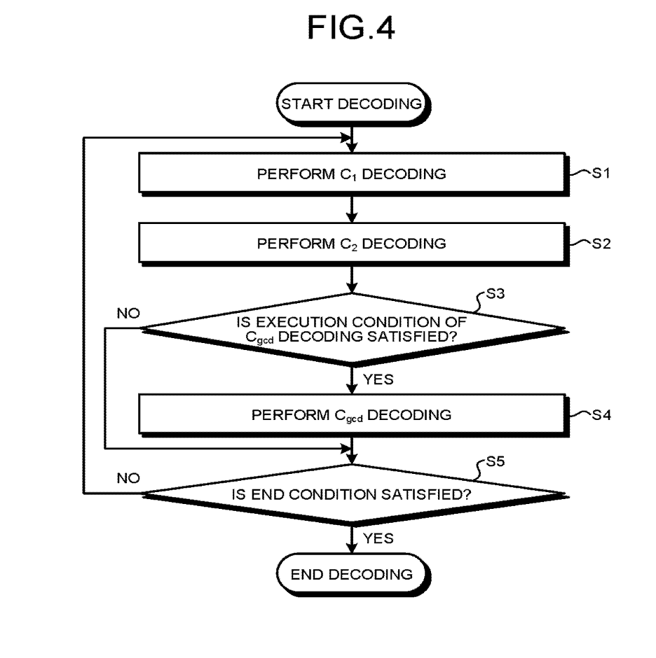

For example, the decoding of the block product code is performed in the following procedure using the decoder 27 illustrated in FIG. 3. FIG. 4 is a diagram illustrating an example of a decoding processing procedure of the block product code according to this embodiment. When the control unit 23 instructs the decoding of the block product code to start, the decoding controller 64 instructs the first decoder 61 to perform the decoding, and the first decoder 61 performs the C₁ decoding in which the decoding algorithm is applied to the code C₁ with respect to the area (from a 0-th row to (r′−1)-th row illustrated in the block product code in FIG. 2) following the code constraint of the code C₁ (Step S1). Next, the decoding controller 64 instructs the second decoder 62 to perform the decoding, and the second decoder 62 performs the C₂ decoding in which the decoding algorithm is applied to the code C₂ with respect to the area (from a 0-th col to (v−1)-th col of the block product code illustrated in FIG. 2) following the code constraint of the code C₂ (Step S2).

Next, the decoding controller 64 determines whether an execution condition of the C_{gcd} decoding in which the decoding algorithm is applied to the code C_{gcd} is satisfied (Step S3). As the execution condition of the C_{gcd} decoding, for example, a condition in which repetition counts of the C₁ decoding and the C₂ decoding are equal to or more than a first threshold may be used. The execution condition of the C_{gcd} decoding is not limited to the above configuration.

In a case where it is determined that the execution condition of the C_{gcd} decoding is satisfied (Yes in Step S3), the decoding controller 64 instructs the third decoder 63 to perform the C_{gcd} decoding, and the third decoder 63 performs the C_{gcd} decoding with respect to the area (from a r′-th row to (r−1)-th row of the block product code illustrated in FIG. 2) following the code constraint of the code C_{gcd} (Step S4).

Next, the decoding controller 64 determines whether an end condition of the decoding of the block product code is satisfied (Step S5). In a case where the end condition of the decoding of the block product code is satisfied (Yes in Step S5), the decoding controller 64 ends the decoding of the block product code. As the end condition of the decoding of the block product code, a condition that all the code words of at least one component code of the code C₁ and the code C₂ satisfy the code constraint may be used. In addition, as the end condition of the decoding of the block product code, a condition that the repetition count is equal to or more than a second threshold may be used.

In Step S3, in a case where it is determined that the execution condition of the C_{gcd} decoding is not satisfied (No in Step S3), the procedure proceeds to Step S5. In Step S5, in a case where it is determined that the end condition of the decoding of the block product code is not satisfied (No in Step S5), the procedure proceeds to Step S1.

The above description has been made about an example in which the hard decision decoding is used for the decoding of the component code, and the soft decision decoding may be used for the decoding of the component code as described above. In a case where the soft decision decoding is performed as the decoding of the component code, as one of the decoding methods corresponding to the entire block product code, there is a method called the turbo decoding in which the external value is exchanged between the component codes.

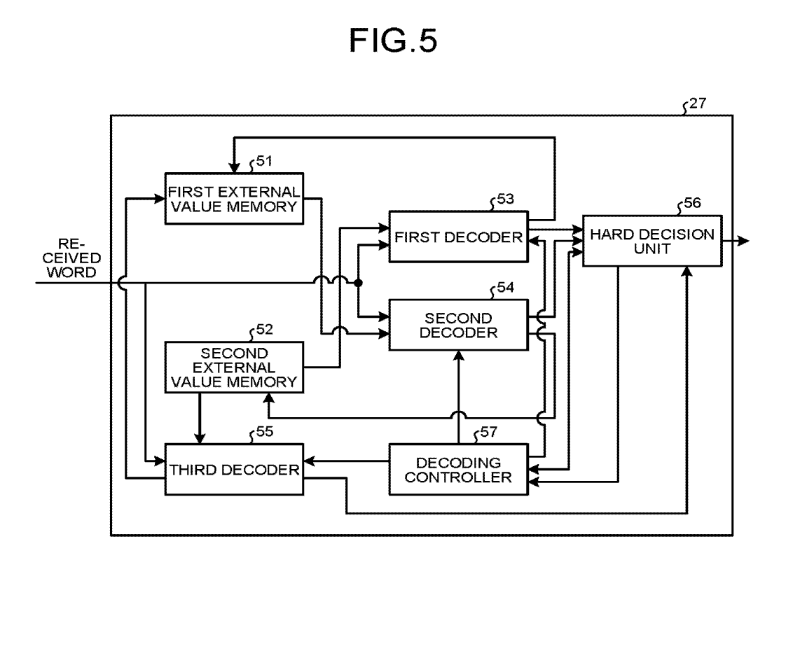

FIG. 5 is a diagram illustrating an exemplary configuration of the decoder 27 in a case where the turbo decoding is performed. As illustrated in FIG. 5, the decoder 27 includes a first external value memory 51, a second external value memory 52, a first decoder 53, a second decoder 54, a third decoder 55, a hard decision unit 56, and a decoding controller 57.

The first decoder 53 performs the soft decision decoding (C₁ decoding) corresponding to the code constraint of the code C₁ using the received word which is previously encoded to a C₁ code word stored in the data buffer 25 or the received word+the external value stored in the second external value memory 52, and stores the external value obtained by the soft decision decoding to the first external value memory 51.

The second decoder 54 performs the soft decision decoding (C₂ decoding) corresponding to the code constraint of the code C₂, using the received word which is previously encoded to a C₂ code word stored in the data buffer 25 or the received word+the external value stored in the first external value memory 51, and stores the external value obtained by the soft decision decoding to the second external value memory 52. In addition, the second decoder 54 outputs a posteriori value obtained by the decoding to the hard decision unit 56.

The third decoder 55 performs the soft decision decoding (C_{gcd} decoding) corresponding to the code constraint of the code C_{gcd}, and updates the external value of the first external value memory 51 with the external value obtained by the soft decision decoding using the symbol group of checks2 and checks2 on checks1 stored in the data buffer 25 (that is, read data corresponding to d_{checks2} in the lowest one row of the block product code illustrated in FIG. 2 or the data+the external value stored in the second external value memory 52). In addition, the third decoder 55 outputs the posteriori value obtained by the decoding to the hard decision unit 56.

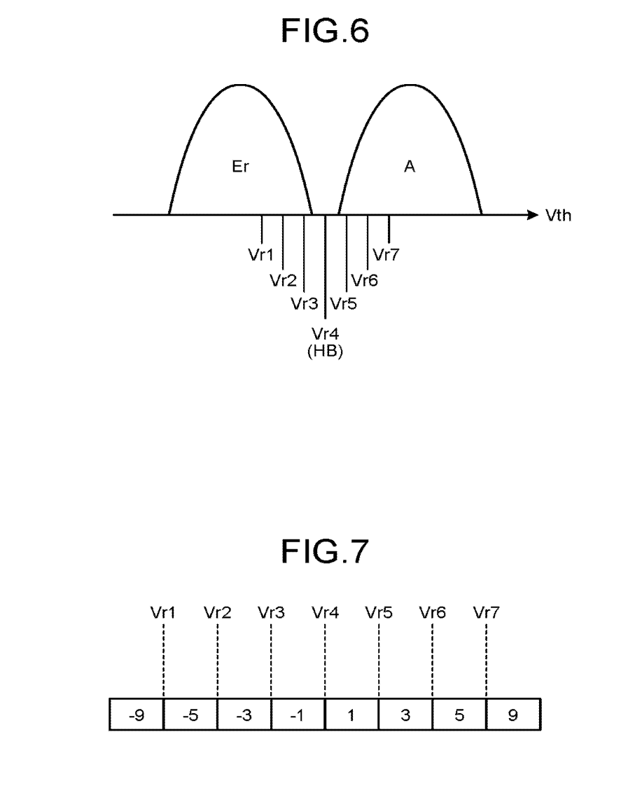

Further, in a case where the soft decision decoding is performed, the hard decision value may be set as an input in the reading from the nonvolatile memory 3 similarly to the case where the above-mentioned hard decision decoding is performed, and a soft decision value may be input. In a case where the soft decision value is input, the reading from the nonvolatile memory 3 is performed by a soft bit read. FIG. 6 is a diagram for describing the soft bit read. The horizontal axis of FIG. 6 shows a threshold voltage, and the vertical axis shows a frequency. FIG. 6 illustrates an example of the single level cell which stores 1 bit/cell in which Er (Erase) distribution on the left side corresponds to data value 1 and A distribution on the right side corresponds to data value 0. In the soft bit read, the reading is performed by a plurality of read voltages such as a read reference voltage and a reference read voltage used in a hard bit read. In the example of FIG. 6, there is illustrated an example in which the soft bit read is performed using a total of seven read voltages. A rad voltage denoted by Vr4 (HB) shows the reference read voltage used in the hard bit read. In the soft bit read, the reading is performed using a total of seven read voltages (Vr4; Vr1, Vr2, and Vr3 lower than Vr4; and Vr5, Vr6, and Vr7 higher than Vr4). Further, the number of read voltages in the soft bit read is not limited to “7”.

Then, for example, a log-likelihood ratio (LLR) table may be used, and the LLR can be obtained from a result of determination on whether the threshold voltage of each memory cell is equal to or more than each read voltage. FIG. 7 is a diagram illustrating an example of the LLR table. For example, in a case where it is determined that the threshold voltage of the memory cell is less than Vr1, the LLR becomes −9, and in a case where it is determined that the threshold voltage of the memory cell is equal to or more than Vr1 and less than Vr2, the LLR becomes −5. FIG. 7 is a mere example, and the LLR table is not limited to the example of FIG. 7. In addition, the LLR may be obtained using a calculating formula without using the LLR table. In this embodiment, a process from the reading of the soft bit read until the threshold voltage is converted into the LLR is called a reading of data from the nonvolatile memory 3 as the soft decision voltage.

The conversion from a result of the determination on whether the threshold voltage of each memory cell is equal to or more than each read voltage may be performed by the memory controller 2 or the nonvolatile memory 3. In a case where the memory controller 2 performs the conversion, for example, the nonvolatile memory 3 outputs information indicating a subject area among eight areas of which the threshold voltages are less than Vr1, Vr1 or more and Vr2 or less, Vr2 or more and Vr3 or less, Vr3 or more and Vr4 or less, Vr4 or more and Vr5 or less, Vr5 or more and Vr6 or less, Vr6 or more and Vr7 or less, Vr7 or more to each memory cell. Then, the memory I/F 22 obtains the LLR based on the LLR table and the information output from the nonvolatile memory 3, and stores the LLR to the data buffer 25.

Further, in FIGS. 6 and 7, the description has been described about an example of the single level cell which stores 1 bit/cell. However, similarly to the example of the single level cell, even in the case of the multi-level cell, the reading is performed for each boundary between the threshold distributions using the plurality of read voltages. Then, the LLR is calculated based on a result of the reading from among the plurality of read voltages.

A decoding procedure of the block product code in a case where the turbo decoding is performed is similar to the decoding processing procedure illustrated in FIG. 4 except that the C₁ decoding, the C₂ decoding, and the C_{gcd} decoding are the soft decision decoding as described above. However, in a case where it is determined in Step S5 that the end condition is satisfied, the decoding controller 57 instructs the hard decision unit 56 to perform the hard decision, and the hard decision unit 56 performs the hard decision on the posteriori value output from the second decoder 54 and outputs the resultant data to the data buffer 25. The control unit 23 makes control on the host I/F 21 such that the user data subjected to the hard decision stored in the data buffer 25 is transmitted to the host 4.

The decoding method in a case where the soft decision decoding is performed using the C₁ decoding, the C₂ decoding, and the C_{gcd} decoding is not particularly limited. For example, a chase decoding may be used.

As described above, in this embodiment, the decoding corresponding to the code constraint with the greatest common divisor between the generator polynomial of the code C₁ and the generator polynomial of the code C₂ is performed on the areas of checks2 and checks2 on checks1 which follow the code constraint of the code C₂ but do not follow the coding constraint of the code C₁ in the block product code. Therefore, it is possible to increase a possibility to correct an error in the areas of checks2 and checks2 on checks1.

### Second Embodiment

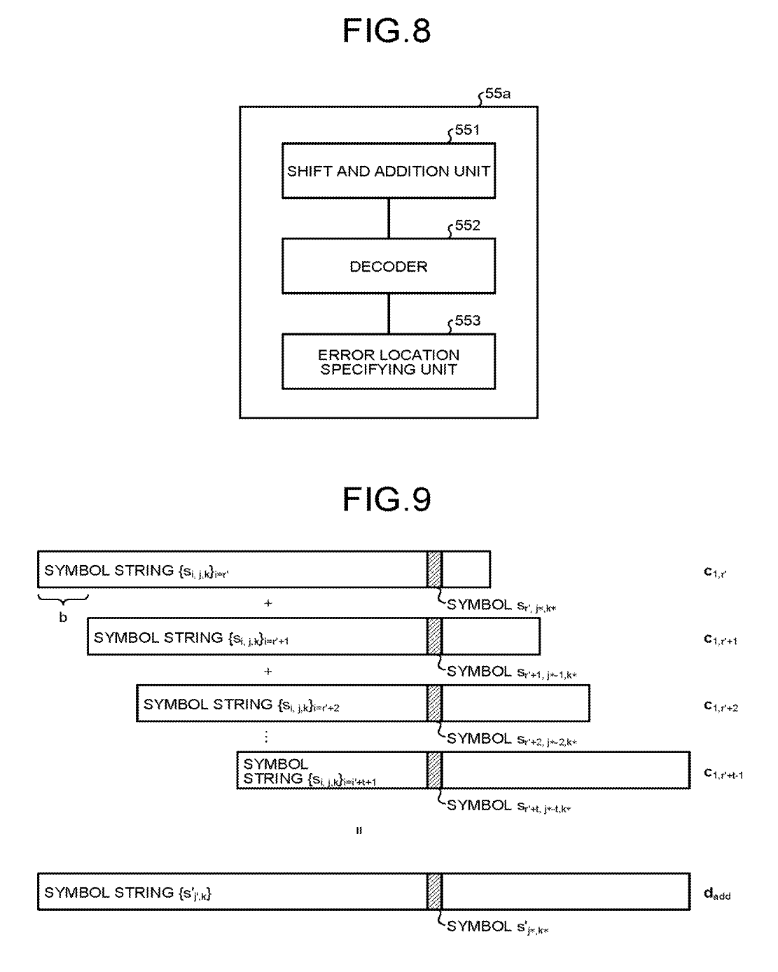

In the first embodiment, the description has been made about an example in which r−r′ is 1. In a second embodiment, the block product code is targeted in a case of where r−r′ is t (t is an integer of 2 or more). In other words, the description will be made about a case where checks2 and checks2 on checks1 are over the t rows. FIG. 8 is a diagram illustrating an exemplary configuration of a third decoder 55a according to this embodiment. The configuration of the storage device according to this embodiment is identical with or similar to the storage device 1 according to the first embodiment except that the third decoder 55 is replaced with the third decoder 55a.

The third decoder 55a includes a shift and addition unit 551, a decoder 552, and an error location specifying unit 553.

Herein, the left side of Equation (7) described in the first embodiment can be expressed as Equation (10) as follows. However, the symbol group s′_{j′,k} in Equation (9) is defined in Equation (10). Further, min(y,z) shows a value of small one of y and z, and max(y,z) shows a value of large one of y and z.

$$\begin{matrix}{\sum }_{{j}^{′} = 0}^{v + t - 2} {\sum }_{k = 0}^{b - 1} {s}_{{j}^{′} , k}^{′} {x}^{( k + {j}^{′} b )} ≡ 0 mod {g}_{gcd} ( x ) & ( 9 ) \\ {s}_{j , k}^{′} := {\sum }_{{i}^{′} = max ( 0 , {j}^{′} - v + 1 )}^{min ( t - 1 , {j}^{′} )} {s}_{{r}^{′} + {i}^{′} , {j}^{′} - {i}^{′} , k} & ( 10 )\end{matrix}$$

The left side of Equation (9) shows that the symbol groups of the respective rows are added as many as one block (that is, b symbols) with respect to the respective symbol groups of the t rows from the r′-th row to the (r−1)-th row of the block product code illustrated in FIG. 2. The right side of Equation (9) is set to d_{add}. In other words, d_{add} is composed of b×(v+t−1) symbols s′_{j′,k}. In addition, it can be analyzed that d_{add} is composed of (v+t−1) virtual blocks. At this time, a k-th symbol in j′-th block in d_{add} is denoted by s′_{j′,k}.

FIG. 9 is a diagram illustrating that the symbol string {s′_{j′,k}} of d_{add} is composed by adding the symbol strings {s_{i,j,k}} which are included in the original codes. FIG. 9 illustrates that c_{1,r′} (the symbol string of the r′-th row), (the symbol string of the (r′+1)-th row), (the symbol string of (r′+t−1)-th row (that is, the (r−1)-th symbol string)) are shifted by one block and added to obtain d_{add}. In FIG. 9, the symbol string {s_{i,j,k}}_{i=r′} which is a subset of the symbol string {s_{i,j,k}} of the block product code is denoted in the rectangular indicating c_{1,r′}, which indicates that c_{1,r′} is composed of the symbol string {s_{i,j,k}}_{i=r′}. This configuration is also the same in c_{1,r′+1}, . . . , c_{1,r′+t-1}. Further, FIG. 9 illustrates that d_{add} includes the symbol strings {s′_{j′,k}} from j=0 to j=v+t−2.

In addition, as illustrated in FIG. 9, it can be seen that the symbol string s′_{j′,k}, when viewed in the vertical direction, is configured by adding the subsets of the symbol string {s_{i,j,k}} of the original code. For example, the symbol s′_{0,k} is equal to the symbol s_{r′,0,k}, the symbol s′_{1,k} is obtained by adding the symbol s_{r′,1,k} and the symbol s_{r′+1,0,k}, and the symbol s′_{r′+t-1,k} is obtained by adding the symbol s_{r′,t-1,k}, the symbol s_{r′+1,t-2,k}, . . . , and the symbols S_{r′+t-1,0,k}.

The symbol group d_{add} made of the symbol string {s′_{j,′k}} belongs to the code constraint of the linear cyclic code C_{gcd} having the code length (v+t−1)b from the above Equation (7). Then, an erroneous symbol s′_{j*,k*} included in d_{add} can be specified by applying the decoding algorithm on the Code C_{gcd} to d_{add}.

However, the specified erroneous symbol s′_{j*,k} is an addition of the subsets of the symbol group {s_{i,j,k}} of the block product code as illustrated in FIG. 9. When the subset is set to a set R_{j*k*}, the set R_{j*,k*} can be expressed by the following Equation (11). In FIG. 9, the symbol made of s′_{j*,k*} and the element of the set R_{j*k*} is hatched.

R_{j*k*}={S_{r′+i′,j*-i′,k*}|ε[max(0,j*−ν+1),min(t−1,j*)]} (11)

Therefore, when |R_{j*k*}|>1 is satisfied, it is not possible to specify a cause of the erroneous symbol s′_{j*,k*} in the elements of the set R_{j*k*} containing s′_{j*,k*}. Therefore, in this embodiment, in order to specify the cause of the error, the symbol having the lowest reliability among the elements of the set R_{j*k*} is considered to have an error. Herein, the reliability of the symbol is a value having a negative correlation with a probability of an error occurring in the symbol (that is, a value having a positive correlation with a probability of the symbol having no error.)

For example, the decoding result of the code C₂ may be used as the above reliability. Depending on the decoding algorithm of the error correction code, when a lot of errors are contained in the received word, the decoding may be failed (the algorithm fails in finding out an appropriate decoding word). Therefore, there is a strong correlation between “the decoding of a certain received word is failed” and “a lot of errors are contained in the received word”.

In the block product code illustrated in FIG. 2, each of the elements contained in the set R_{j*k*} belongs to an code constraint of the code word of the independent code C₂. Therefore, in a case where there is a symbol failed in the correction due to only one code C₂ among the symbols contained in the set Rᵢ*ₖ*, by specifying the symbol as the cause of the error, it is possible to specify a symbol which has an error in each of the t symbol groups from r′-th row to (r−1)-th row.

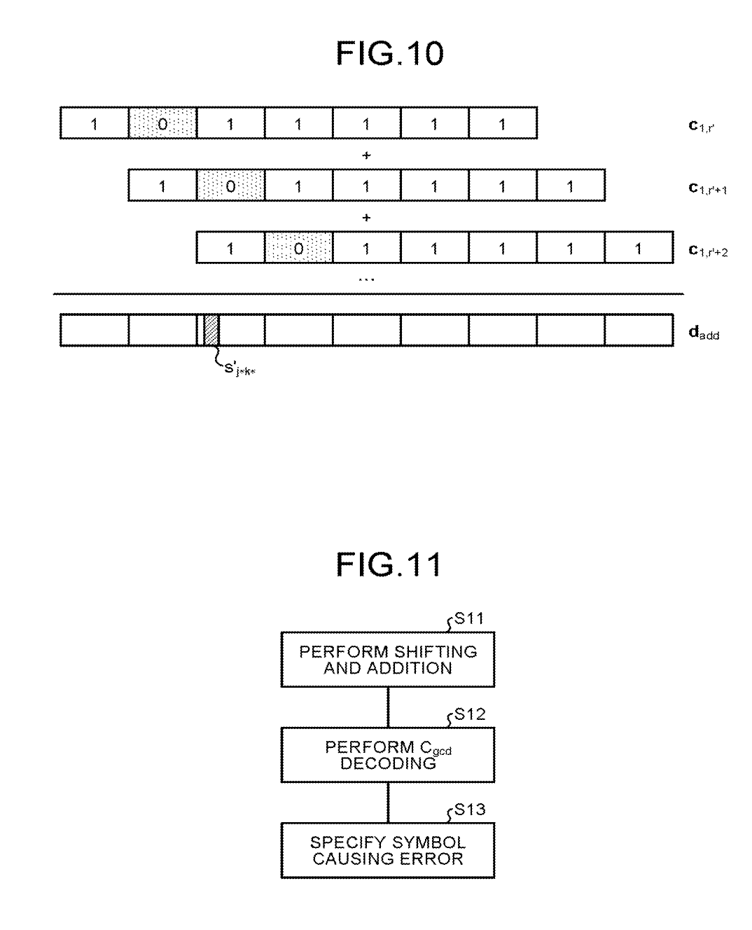

FIG. 10 is a diagram illustrating an example of a relation between a symbol failed in the correction due to the code C₂ and the symbol s′_{j*,k*} specified as having an error in the decoding of d_{add}. As illustrated in FIG. 10, j* is set to 2 (that is, s′_{j*,k*} specified as having an error in the decoding of d_{add} is set to s′_{2,k*}). In this case, in the decoding of the code C₂, the received word corresponding to j=1 (that is, the code word c_{2,1} of the code C₂ in the second row from the left side in the block product code of FIG. 2) is failed in the decoding, the received word corresponding to the code word of the code C₂ in another row is successful in the decoding. Further, in the FIG. 10, in the case where the numeric value in the block is 0, the received word which is previously encoded to a C₂ code word containing the subject block is shown as being successful in the C₂ decoding. In a case where the numeric value in the block is 1, the received word which is previously encoded to a C₂ code word containing the subject block is shown as being failed in the C₂ decoding. In the example illustrated in FIG. 10, the symbols s_{r′,2,k*}, S_{r′+1,1,k*}, and s_{r′+2,0,k*} are contained in the set R₂ₖ* of the symbol string forming s′_{2,k*}. Among them, the symbol contained in the received word which is previously encoded to a C2 code word and failed in the C2 decoding is only s_{r′+1,1,k*}. Therefore, it is possible to specify that s_{r′+1,1,k*} is a cause of the error of s′_{2,k*} (that is, s_{r′+1,1,k*} has an error).

In addition, as another example of the reliability, for example, a probability distribution of the values of the respective symbols obtained in the soft decision decoding may be employed. As an example, here is considered a case where the possible values of the respective symbols are any one of 0 and 1 (binary symbol). In a decoding process called the soft decision decoding, the probability values P(s_{i,j,k}=0) and P(s_{i,j,k}=1) are calculated for each of the possible values of the symbols s_{i,j,k}. At this time, a value called a log-likelihood ratio (LLR) obtained by taking the logarithm of a ratio of P(s_{i,j,k}=0) and P(s_{i,j,k}=1) is used in some cases, but an absolute value of the LLR is taken, a value larger than that in a case where an estimated value of the symbol is a great likelihood, and becomes a value approaching 0 compared to a case where the estimated value is less likelihood. Therefore, it can be considered that there is an error in the symbol having the lowest absolute value of the LLR among the symbols contained in the set R_{j*k*}.

Therefore, as described in the first embodiment, in a case where the LLR is used for an input value of the soft decision decoding, the absolute value of the input value LLR may be used as the reliability.

FIG. 11 is a diagram illustrating an example of a decoding procedure of the areas checks2 and checks2 on checks1 according to this embodiment. First, the shift and addition unit 551 performs a shifting of data of each row and an addition of the shifted data according to Equation (9) (Step S11). Next, the decoder 552 performs the C_{gcd} decoding on d_{add} obtained in Step S11 (Step S12). Then, the error location specifying unit 553 specifies the original symbol causing an error of the symbol which is determined as having an error by the C_{gcd} decoding, and sets the specified result as the decoding result (Step S13), and then the process is ended.

Further, as the reliability, in a case where information indicating whether the symbol is successful in the C₂ decoding is used, and in a case where a symbol failed in the C₂ decoding two or more times is contained in the set R_{j*k*} of the symbol string forming s′_{j*,k*}, it is not possible to specify a symbol which causes an error. Therefore, in this case, it is determined that the decoding of checks2 and checks2 on checks1 is failed, or another reliability is used as well.

In addition, in a case where the received word is the soft decision value, for example, the following process is performed. The shift and addition unit 551 calculates d_{add} as the soft decision value, and the decoder 552 uses this d_{add} as an input and performs the C_{gcd} decoding which is a soft input hard output (SIHO) decoding, and specifies a location of the symbol having a high probability of causing an error in d_{add} based on a hard output. Then, the error location specifying unit 553 determines the symbol in the block product code which is highly likely to cause the symbol to have an error in d_{add} with a high probability based on the reliability as described above. Then, the fact that the symbol in the block product code which is highly likely to cause the symbol to have an error in d_{add} with a high probability has a high probability to cause an error, and the other symbols in the block product code have a low probability to cause an error is reflected on the external value.

Further, the process in a case where the received word is the soft decision value is not limited to the above example. For example, the shift and addition unit 551 calculates d_{add} as the soft decision value, and the decoder 552 creates a list of combinations of the symbols of the block product code which satisfies the code constraint of the code C_{gcd} with the use of d_{add} as an input. Then, a procedure (list-based SISO decoding) may be used in which an external value for each symbol of the block product code is calculated based on the probability to cause an error in the combination of the values of the block product codes contained in the list.

As described above, in this embodiment, in a case where there are two or more rows of checks2 and checks2 on checks1, the C_{gcd} decoding is performed on the data obtained by shifting and adding the received word of each row. Then, the symbol causing an error of the symbol which is determined as having an error by the C_{gcd} decoding is obtained based on the reliability. Even in a case where there are two or more rows of checks2 and checks2 on checks1, it is possible to increase the possibility to correct the error of the areas of checks2 and checks2 on checks1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller comprising:
an encoder configured to generate a block product code which includes a first code and a second code as component codes, the first code and the second code being linear cyclic codes;
a memory interface configured to write the block product code to a nonvolatile memory, and to read a received word corresponding to the block product code from the nonvolatile memory; and
a decoder configured to perform a decoding with respect to a symbol of an area using a code constraint, the code constraint corresponding to a third generator polynomial, the third generator polynomial being a common divisor between a first generator polynomial and a second generator polynomial, the first generator polynomial being a generator polynomial of the first code, the second generator polynomial being a generator polynomial of the second code, the area being included in the block product code and not subjected to a code constraint of the first code but subjected to a code constraint of the second code in the received word.

2. The memory controller according to claim 1,
wherein the first generator polynomial and the second generator polynomial are not coprime.

3. The memory controller according to claim 1,
wherein the decoder is configured to add an element of a first symbol group included in the area, the decoding includes a decoding with respect to a second symbol group using the code constraint corresponding to the third generator polynomial, the second symbol group being obtained as a result of the adding.

4. The memory controller according to claim 3,
wherein the decoder is configured to specify a symbol having an error among symbols included in the first symbol group based on reliability information of the symbols, the first symbol group being an addition source of a symbol included in the second symbol group determined as an error by the decoding using the code constraint corresponding to the third generator polynomial.

5. The memory controller according to claim 1,
wherein the decoder is configured to perform:
a first decoding which is a decoding a symbol of an area which is subjected to the code constraint of the first code in the received word using the code constraint of the first code,
a second decoding which is a decoding a symbol of an area which is subjected to the code constraint of the second code in the received word using the code constraint of the second code, and
in a case where a condition is satisfied,
a third decoding on a symbol of the area, the third decoding which is a decoding using the code constraint corresponding to the third generator polynomial.

6. The memory controller according to claim 5,
wherein the decoder repeatedly performs the first decoding, the second decoding, and the third decoding until an end condition is satisfied.

7. The memory controller according to claim 1,
wherein the first or the second codes is a Bose-Chaudhuri-Hocquenghem code.

8. The memory controller according to claim 1,
wherein the first or the second codes is a Reed-Solomon code.

9. A memory system comprising:
a nonvolatile memory;
an encoder configured to generate a block product code which includes a first code and a second code as component codes, the first code and the second code being linear cyclic codes;
a memory interface configured to write the block product code to a nonvolatile memory, and to read a received word corresponding to the block product code from the nonvolatile memory; and
a decoder configured to perform a decoding with respect to a symbol of an area using a code constraint, the code constraint corresponding to a third generator polynomial, the third generator polynomial being a common divisor between a first generator polynomial and a second generator polynomial, the first generator polynomial being a generator polynomial of the first code, the second generator polynomial being a generator polynomial of the second code, the area being included in the block product code and not subjected to a code constraint of the first code but subjected to a code constraint of the second code in the received word.

10. The memory system according to claim 9,
wherein the first generator polynomial and the second generator polynomial are not coprime.

11. The memory system according to claim 9,
wherein the decoder is configured to add an element of a first symbol group included in the area, the decoding includes a decoding with respect to a second symbol group using the code constraint corresponding to the third generator polynomial, the second symbol group being obtained as a result of the adding.

12. The memory system according to claim 11,
wherein the decoder is configured to specify a symbol having an error among symbols included in the first symbol group based on reliability information of the symbols, the first symbol group being an addition source of a symbol included in the second symbol group determined as an error by the decoding using the code constraint corresponding to the third generator polynomial.

13. The memory system according to claim 9,
wherein the decoder is configured to perform:
a first decoding which is a decoding a symbol of an area which is subjected to the code constraint of the first code in the received word using the code constraint of the first code,
a second decoding which is a decoding a symbol of an area which is subjected to the code constraint of the second code in the received word using the code constraint of the second code, and
in a case where a condition is satisfied,
a third decoding on a symbol of the area, the third decoding which is a decoding using the code constraint corresponding to the third generator polynomial.

14. The memory system according to claim 13,
wherein the decoder repeatedly performs the first decoding, the second decoding, and the third decoding until an end condition is satisfied.

15. The memory system according to claim 9,
wherein the first or the second codes is a Bose-Chaudhuri-Hocquenghem code.

16. The memory system according to claim 9,
wherein the first or the second codes is a Reed-Solomon code.

17. A decoding method comprising:
generating a block product code which includes a first code and a second code as component codes, the first code and the second code being linear cyclic codes;
writing the block product code to a nonvolatile memory;
reading a received word corresponding to the block product code from the nonvolatile memory; and
performing a decoding with respect to a symbol of an area using a code constraint, the code constraint corresponding to a third generator polynomial, the third generator polynomial being a common divisor between a first generator polynomial and a second generator polynomial, the first generator polynomial being a generator polynomial of the first code, the second generator polynomial being a generator polynomial of the second code, the area being included in the block product code and not subjected to a code constraint of the first code but subjected to a code constraint of the second code in the read received word.

18. A decoding method according to claim 17,
wherein the first generator polynomial and the second generator polynomial are not coprime.

19. A decoding method according to claim 17, wherein the performing includes:
adding an element of a first symbol group included in the area; and
a decoding with respect to a second symbol group using the code constraint corresponding to the third generator polynomial, the second symbol group being obtained as a result of the adding.

20. A decoding method according to claim 19, wherein the performing includes specifying a symbol having an error among symbols included in the first symbol group based on reliability information of the symbols, the first symbol group being an addition source of a symbol included in the second symbol group determined as an error by the decoding using the code constraint corresponding to the third generator polynomial.
